(19) United States
(12) Patent Application Publication
(10) Pub. No.: US 2014/0092536 A1
(43) Pub. Date: Apr. 3, 2014

(54) CASE UTILIZING REINFORCED FILM FOR IN-MOLD LABELING

(71) Applicant: Speculative Product Design, LLC, Mountain View, C (US)

(72) Inventors: Jon Karl DUKERSCHEIN, San Francisco, CA (US); Bryan Lee Hynecek, Redwood City, CA (US); Jordan Robert Fountain, Millbrae, CA (US)

(73) Assignee: Speculative Product Design, LLC, Mountain View, CA (US)

(21) Appl. No.: 14/036,390

(22) Filed: Sep. 25, 2013

Related U.S. Application Data
(60) Provisional application No. 61/705,300, filed on Sep. 25, 2012.

(51) Int. Cl. H05K 5/02

(52) U.S. Cl. CPC H05K 5/02
USPC 361/679.01

(57) ABSTRACT

Described is a case for enclosing a personal electronic device including a first layer co-molded with a second layer and permanently affixed together to form a one-piece assembly; and a reinforcing member. The first layer includes a bottom surface, side surfaces joined to the bottom surface and extending upward therefrom, and a fitted cavity configured to accept and retain the personal electronic device such that the bottom surface covers at least a portion of a bottom surface of the inserted personal electronic device and the side surfaces cover at least a portion of a side surface of the inserted personal electronic device. The second layer includes a bottom surface and side surfaces sized and shaped to cover an exterior of the bottom and side surfaces of the first layer. The reinforcing member is configured to strengthen areas of the second layer.

### CROSS REFERENCE TO RELATED APPLICATION

This application claims priority of U.S. Provisional Application Ser. No. 61/705,300, filed Sep. 25, 2012, which is incorporated by reference herein in its entirety.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyrights whatsoever.

### BACKGROUND

The present disclosure relates generally to cases for enclosing a portable electronic device.

Cases for enclosing a portable electronic device may be one-piece or multiple pieces. Exemplary cases may include multiple layers, such as a flexible inner layer manufactured from a thermoplastic elastomer, thermoplastic polyurethane or silicon compound, and an exterior layer, such as a rigid or thin film exterior layer. According to embodiments, cases may also include reinforcing portions or splints embedded within portions of the case to minimize deformities encountered during manufacturing as well as reinforcing the case in areas generally susceptible to consumer wear.

The flexible inner layer and/or the exterior layer may act to protect an enclosed personal electronic device from damage due to, for example, exposure to dirt contaminants, impact, or shock. The case may be flexible enough so that it deforms to accommodate the insertion of a portable electronic device and, following insertion, returns to its original shape. The case may include a mechanism for maintaining the attachment between the case and the portable electronic device. Exemplary attachment mechanisms include a clip, an extension, an adhesive material, and a magnetic material.

Cases may incorporate In-Mold Labeling (“IML”) or In-Mold Design (“IMD”). IML or IMD are common manufacturing methods that utilize a printed film to decorate hard/soft plastic parts. The film may be a PC, PC/PMMA, or PET type film or substrate which may be printed with layers of ink, creating a specified graphic, which is then inserted into a mold where the film is over molded with a hard or soft plastic.

One problem with existing IML or IMD processes, however, is that the film's substrate material may have properties that are inherently different then the properties of the injection plastic properties. Another problem is forming of the film material to a draw depth of the specific electronic device. Deeper draws results in thinner film (i.e., the film stretches as it draws) which are inherently weaker around cut openings, thereby increasing the need for reinforcement. A deeper draw, however, results in a better overall design, as it allows for coverage of the entire electronic device.

To avoid this problem, many manufacturers often injection mold with a material that has similar properties to the film being used. That is, many manufacturers use injection mold plastic such as polycarbonate with a polycarbonate film thereby eliminating design features that result in film or ink cracking or splitting due to a difference in materials. However, it is not always desirable to use the same film and injection mold plastic, especially when it is desired to achieve a product such as a personal electronics device case, with both a hard and soft layer. For example, if a personal electronics device case incorporates an injection molded plastic that has a much higher elastic deformation properties then those compared to the film substrate i.e., injection mold thermoplastic elastomer or polyurethane combined to a polycarbonate/polyester film, there may be issues with deformations and wear. Secondly, thin areas of the case, which may be mostly film, when combined with an elastic material such as TPE/TPU, allows the thin areas of film to stretch during injection molding or consumer use, which often result in the risk of wear and breakage due to cracking during molding or use.

Accordingly, a need exists to reduce the risk of wear and breakage. By utilizing materials with different properties, case utility and design may be enhanced.

### SUMMARY

According to embodiments, the risk of wear and breakage in a case may be reduced by including, during the manufacturing process, a hard plastic rib or splint into the molding process that reinforces areas susceptible to such wear and breakage. The use of a rib may be achieved in multiple ways.

In an embodiment, a thin splint or rib of rigid material can be added to the in-mold label film after the film has been formed and cut. The splint may be applied to areas that are prone to breaking, warping, or distortion due to injection of a substrate material or consumer use (i.e., putting the electronic device in and out of the protective case). One or more splints may be used depending on the regions sought to be reinforced.

In an embodiment, splints may be added utilizing any known method that increases the thickness and the strength of the thinner film in areas around cut outs in the film, including but not limited to gluing the splint to the film by hand or automated process, or by local injection molding the splint materials directly to the film before the IML injection step. Additionally and/or alternatively, in an embodiment, the rib or splint may be a rigid reinforced rib configured to fit within the case. The rigid reinforced rib can be added to the assembly that would be molded initially and over molded with a soft plastic afterwards. The rigid reinforced rib may be one overall piece or frame or may be comprised of multiple pieces that may be over molded with a softer plastic at the same time the film is over molded.

Because of the addition of localized reinforced splint material, electronic device cases with thin areas where film breakage or distortion would typically occur can be manufactured without such failures. The addition of rigid splint material allows thin areas in parts of the cases that were previously unattainable, due to film breakage or distortion during the injection molding process or consumer use utilizing, e.g., the methods herein described. Embodiments can also improve product yield during the manufacturing process by reducing deformation in desired areas, thereby improving product manufacturability and consistency.

The films may be sized ranging from 0.178 mm to 0.5 mm. As will be appreciated by those skilled in the art, the thinner films form much finer detailed designs and are easier to form in deep draw conditions, but they also are easier to deform and break. Thicker films do not produce as intricate detail designs, are harder to form in deep draw conditions, but offer more rigidity and protection to the case as a whole.

When adding internal braces or splints to eliminate stretching of the film in certain areas, film of either 0.188 mm or 0.25 mm thickness allows for deep draw forming and detailed designs.

### BRIEF DESCRIPTION OF THE DRAWINGS

The invention is illustrated in the figures of the accompanying drawings, which are meant to be exemplary and not limiting, and in which like references are intended to refer to like or corresponding parts.

FIG. 1 depicts a perspective view of a film layer of a case in an embodiment of the present disclosure.

FIG. 2 depicts a close up of the film of FIG. 1 with reinforcing splints placed in the corner of the film in accordance with an embodiment of the present disclosure.

FIGS. 3A and 3B depict perspective views of a trimmed film layer with reinforced splints in accordance with an embodiment of the present disclosure.

FIG. 4 depicts a perspective view of a finished personal electronics case in accordance with an embodiment of the present disclosure.

FIG. 5 depicts a perspective view of typical areas of deformity found in existing cases that do not utilize the splints or reinforcement methods disclosed by the present disclosure.

FIG. 6 depicts a perspective view of areas of a personal electronic device case where reinforced bridging splints may be placed in accordance with the present disclosure.

FIG. 7 depicts a cross-sectional view of a personal electronics case utilizing the reinforcing splints of the present disclosure.

FIG. 8 depicts a perspective view of a frame insert-type reinforcing splint in accordance with an embodiment of the present disclosure.

FIG. 9 depicts an exploded view of a personal electronic device case manufactured in accordance with an embodiment of the present disclosure.

FIG. 10 depicts a perspective view of a personal electronic device case outer film prior to over molding in accordance with an embodiment of the present disclosure.

FIGS. 11A-C depict various views of a personal electronic device case made in accordance with an embodiment of the present disclosure

FIGS. 12A-F depict various views of a personal electronic device case made in accordance with an embodiment of the present disclosure.

FIG. 13 depicts a cross-sectional view of a molding technique in accordance with an embodiment of the present disclosure.

### DETAILED DESCRIPTION

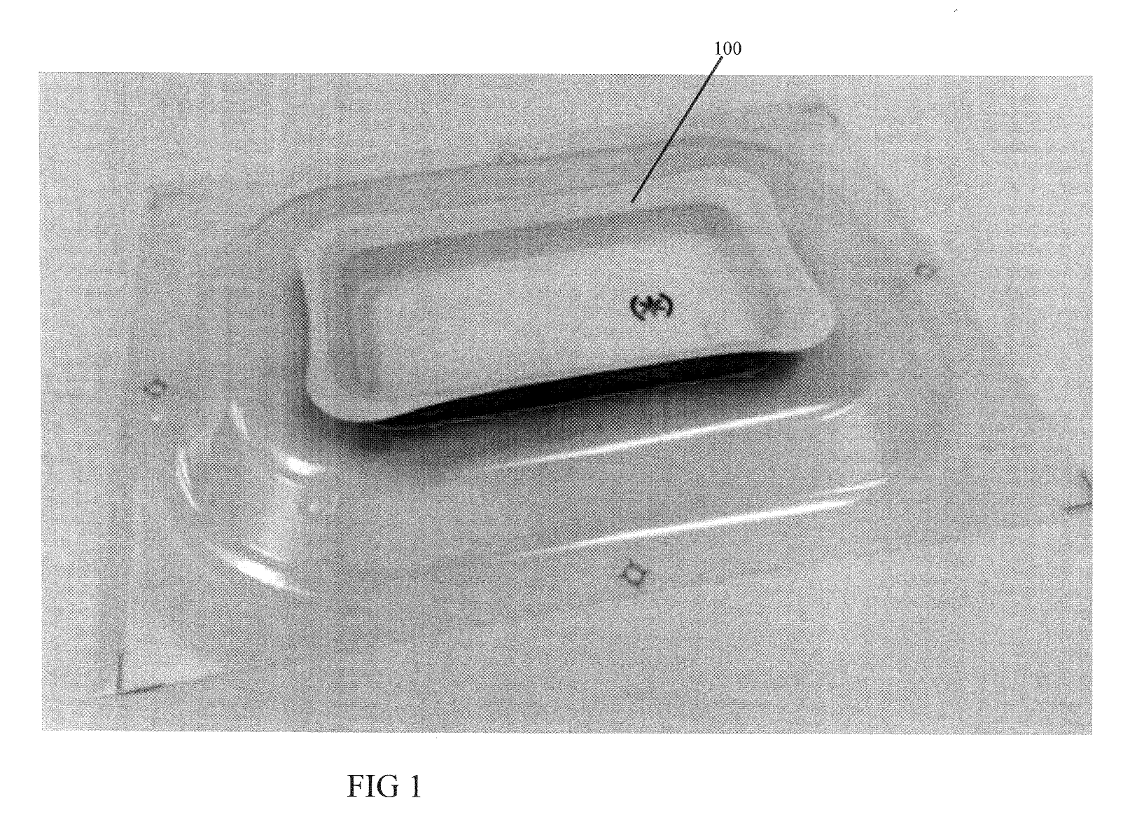

FIG. 1 depicts film form 100 untrimmed and before any over molding process has been performed. Film form 100 may be colored or contain graphics. It may be textured and contain any other decorative features desired.

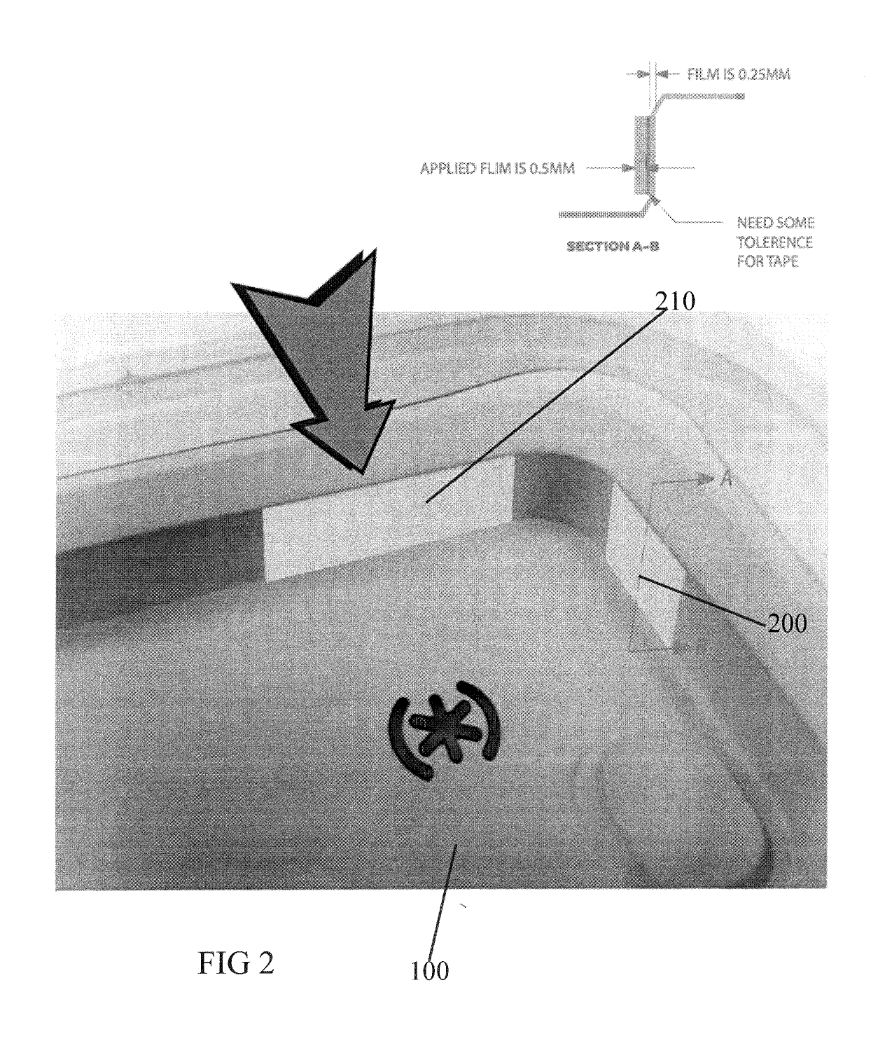

FIG. 2 depicts a close up of film 100 with splints 200 and 210 placed in specific areas to reinforce the film. Splints 200 and 210 may be configured from additional film or tape of 0.2-1.0 mm in thickness with 0.5 mm being an acceptable thickness in one embodiment. Splints 200 and 210 may be applied in other areas of film form 100 and may be applied using pressure bond adhesive tape. Other methods of application such as adhesion utilizing glue, clips, mechanical fasteners, heat or chemical bonding may also be employed to hold splints 200 and 210 in place. Splints may be placed in position utilizing temporary fasteners which may be removed after over molding or may be permanently placed.

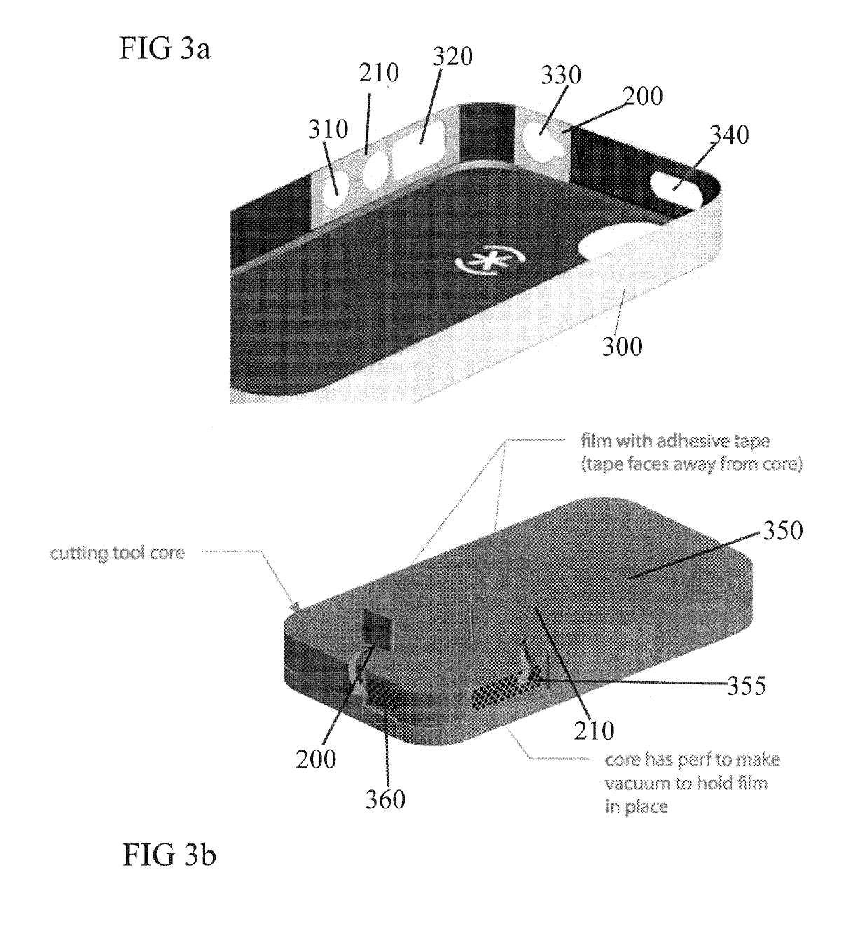

FIG. 3A depicts outer shell 300 with various cutouts 310-340 made from film form 100 after it has been trimmed. As can be seen in FIG. 3A, cut outs 310, 320, and 330 may go through both film form 100 and splints 200 and 210. In contrast, cut out 340 is only made through film form 100 as no splint is located in the area of cut out 340.

FIG. 3B depicts a cutting tool core 350 which may be used to apply splints 200 and 210 directly to the film form 100 during the manufacturing process. In an embodiment, cutting tool core 350 may have areas 355 and 360 which are perforated such that splints 200 and 210 may be retained in place by a vacuum drawing air through perforations 355 and 360 until the splints 200 and 210 are placed within film form 100. By utilizing an automated method, more consistent placement of the splints may be achieved. In addition to perforations 355 and 360, other methods of retaining the splints for placement during the manufacturing process may be employed by, for example, clips, pressure fittings, notches, recessed cavities, tacky adhesive, or any other means for retaining and placing splints 200 and 210 during the manufacturing process.

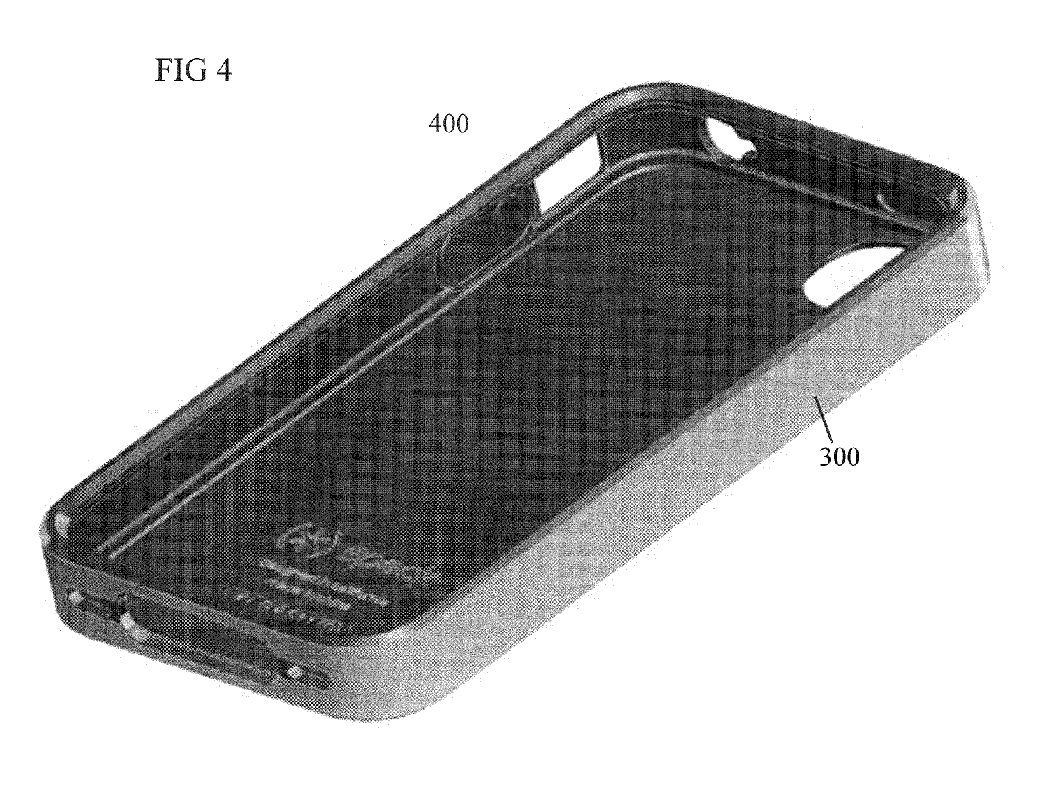

FIG. 4 depicts a finished personal electronic device case 400. Case 400 as depicted in the embodiment of FIG. 4 has been over molded with TPU. To achieve this final case 400, outer shell 300 made from film with the cutouts 310-340 and splints 200 and 210 may be placed in an injection mold and co-molded with TPU or other rigid or pliable materials such as Thermoplastic elastomers, TPU, TPE, silicone, polycarbonate (“PC”), nylon, or polypropylene (“PP”) materials. Additionally, cut out covers, button covers, or other components (not shown) may be added to outer shell 300 prior to the injection molding process.

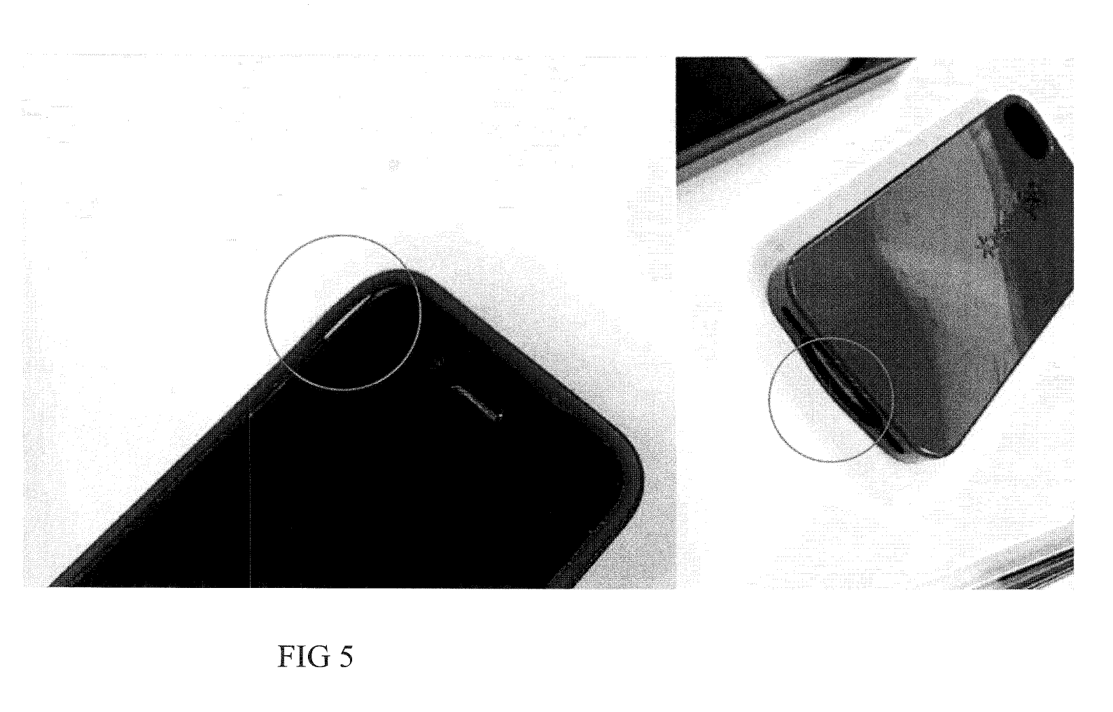

FIG. 5 depicts deformations, wear, and breakage that may occur during the molding process when a personal electronic device case is, e.g., not manufactured in accordance with embodiments of the present disclosure. These deformities may occur when a case is removed from a mold, as a result of material differences, or by consumer wear. By placing splints in these locations, the manufacturing and breakage problems can be greatly reduced.

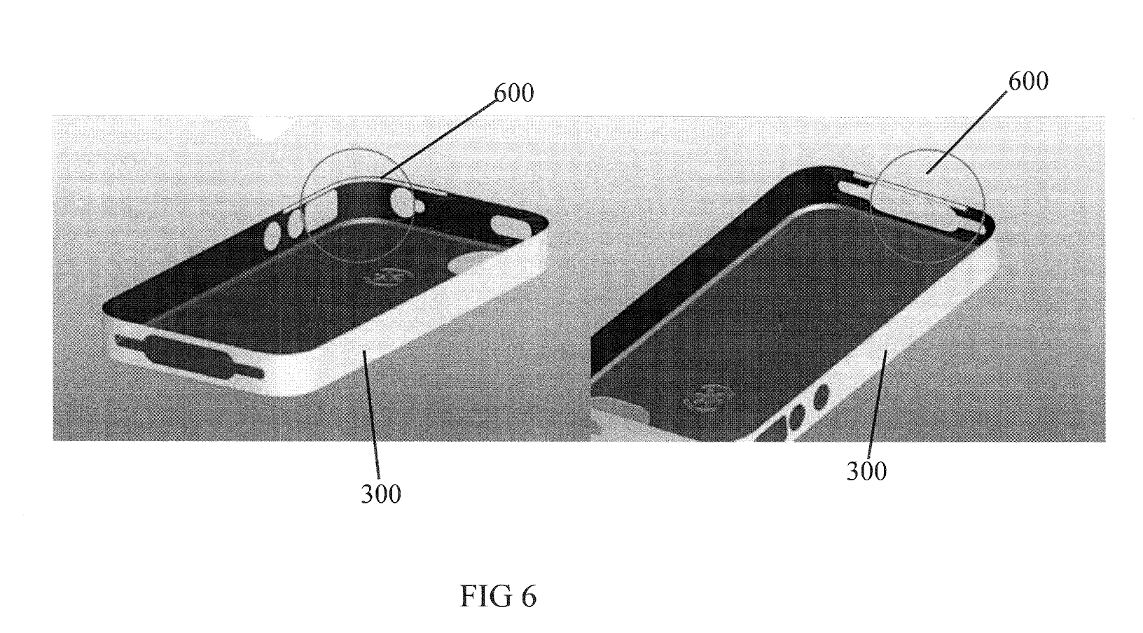

FIG. 6 depicts outer shell 300 with machined bridge splints 600 located at different positions on outer shell 300. Bridge splints 600 may be manufactured from any rigid material such as polycarbonate or metal and placed on outer shell 300 prior to the over molding process to reduce and prevent deforming and to strengthen potentially thin or weak areas of the finished case.

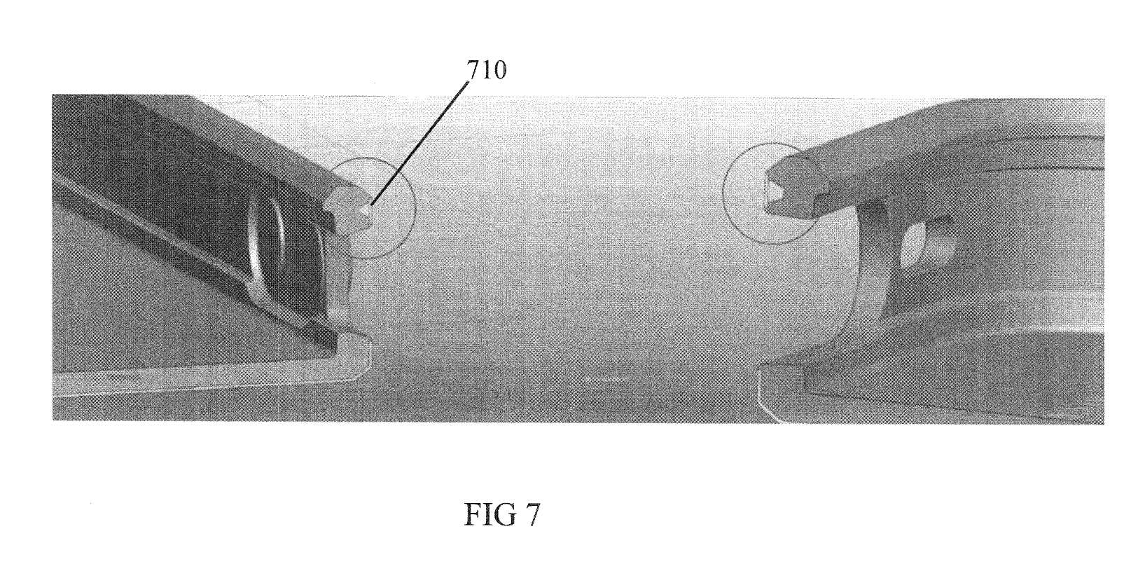

FIG. 7 depicts bridge splint 710 embedded and hidden in the over molded TPU of a finished personal electronic device case.

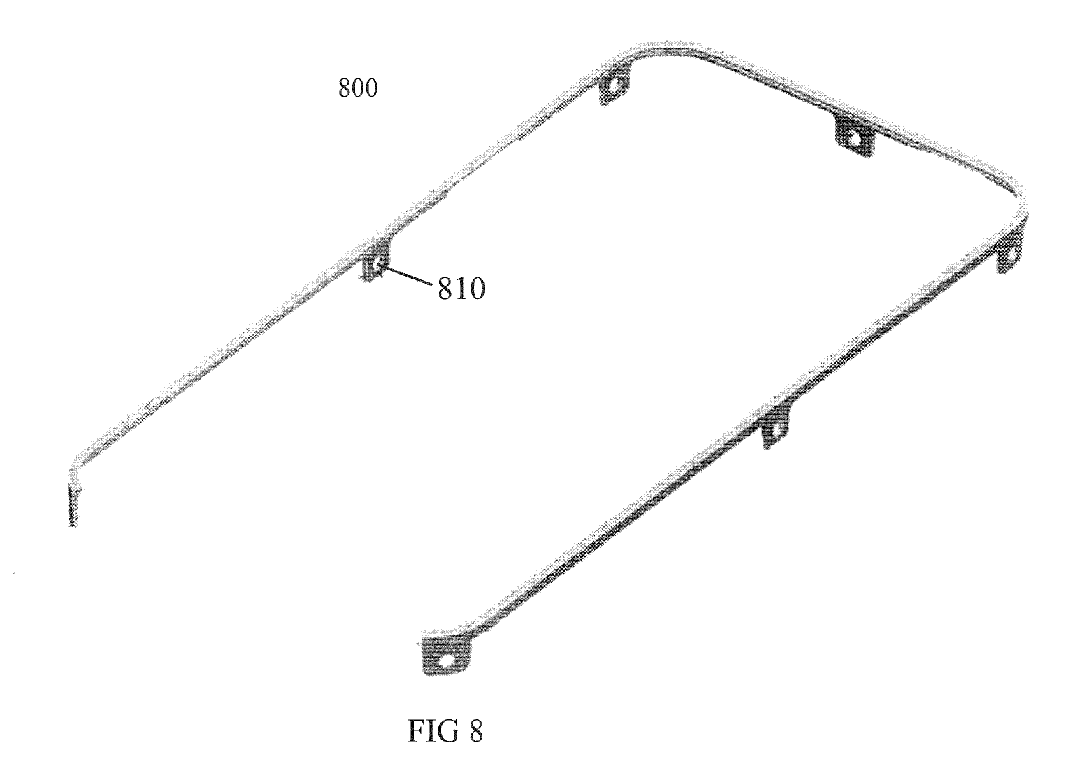

FIG. 8 depicts a frame insert 800 used in an embodiment. Frame insert 800 may be constructed of any rigid material and may be made from polycarbonate, plastic, metal or other materials. It may encompass the entire perimeter of the personal electronic case or may be used only in specific areas. Frame insert 800 may have positioning tabs 810 or similar means to locate and place the frame insert in the film during the molding process. The frame insert can be placed manually within the mold or may be suspended from the mold core and retained in position during the molding process. Retractable pins may be used to hold frame insert 800 in place during molding or other types of clips or retaining means may be used.

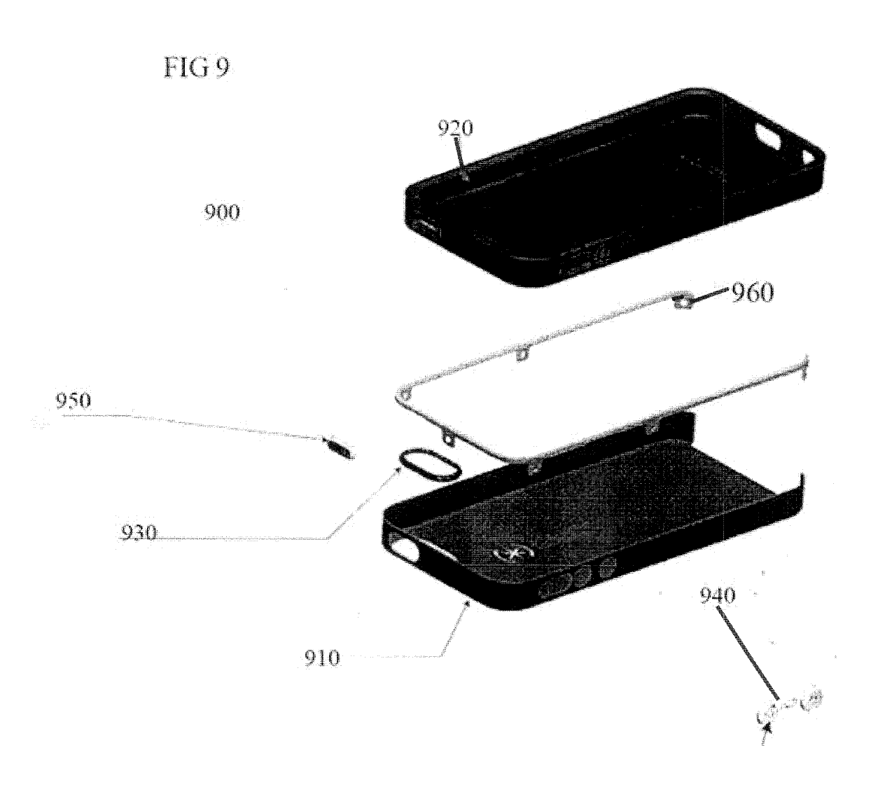

FIG. 9 depicts an exploded view of exemplary components that may be employed to construct a case in accordance with an embodiment. The exemplary case comprises trimmed outer case 910, inner molded liner 920, accessory ring 930, which may be used for a camera, lens, or flash opening, button covers 940 and 950, which are molded into and incorporated into the final case during the over molding process, and frame insert 960.

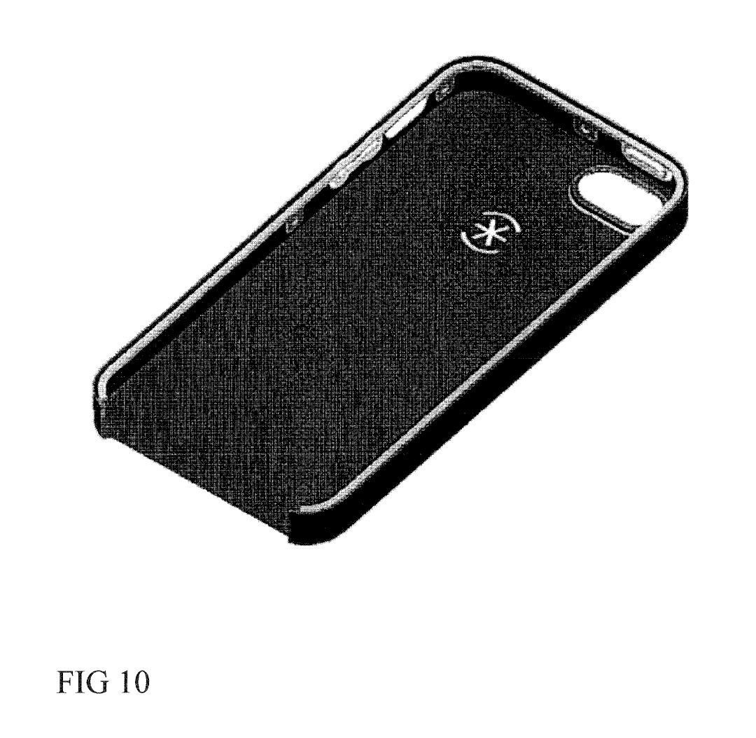

FIG. 10 depicts the components of FIG. 9 arranged prior to the addition of the over molded inner liner 920.

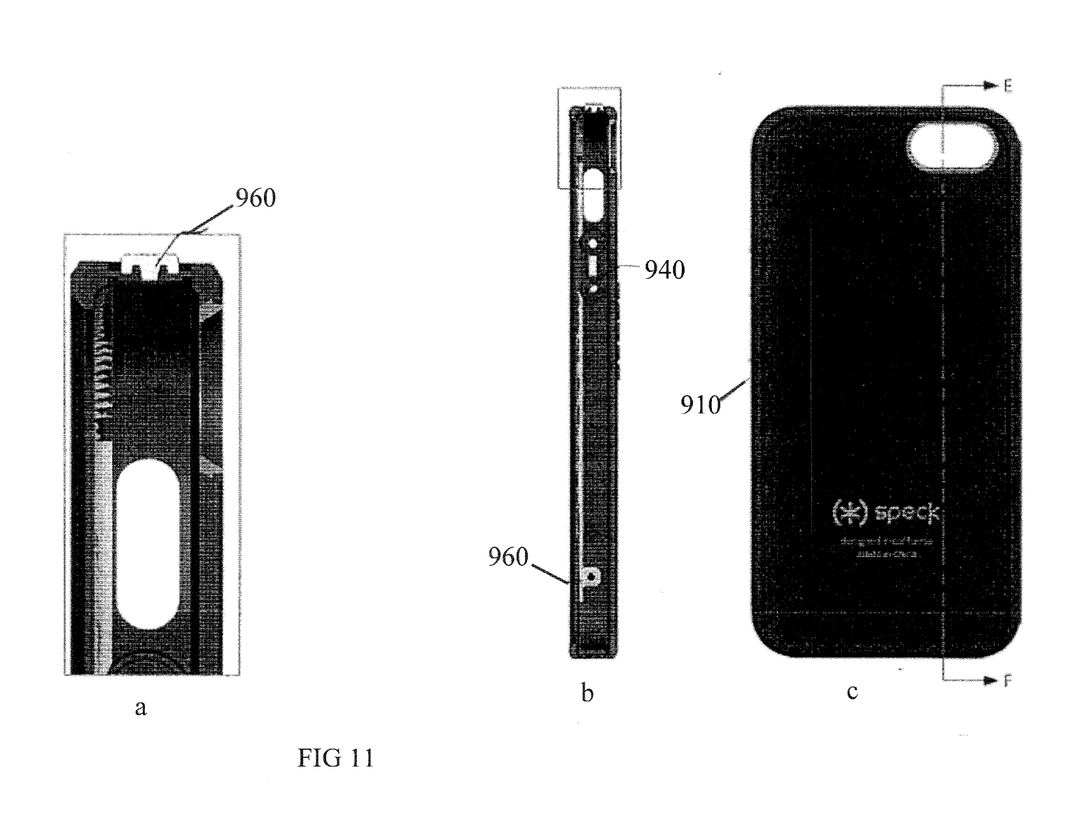

FIGS. 11A-C depict various cross-sectional views of the case and components depicted in FIGS. 9 and 10.

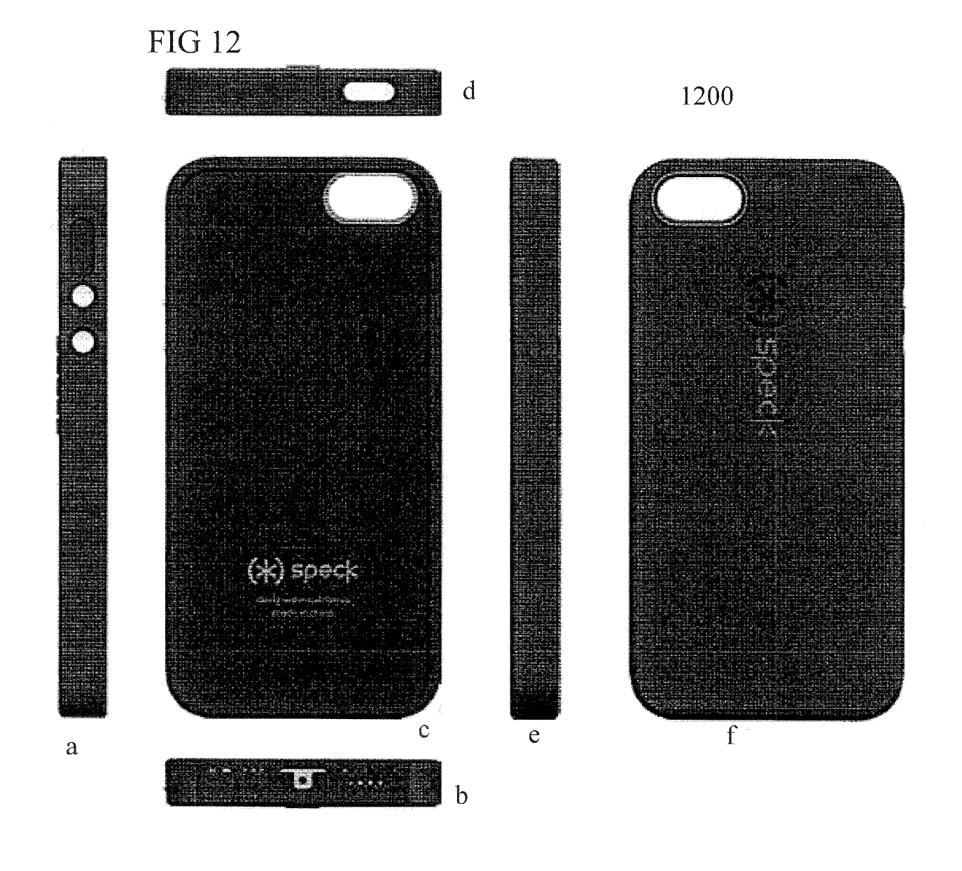

FIG. 12 depicts a case made in accordance with an embodiment of the present disclosure. The case may be made with a thin film outer surface or may be made from a thin metallic film.

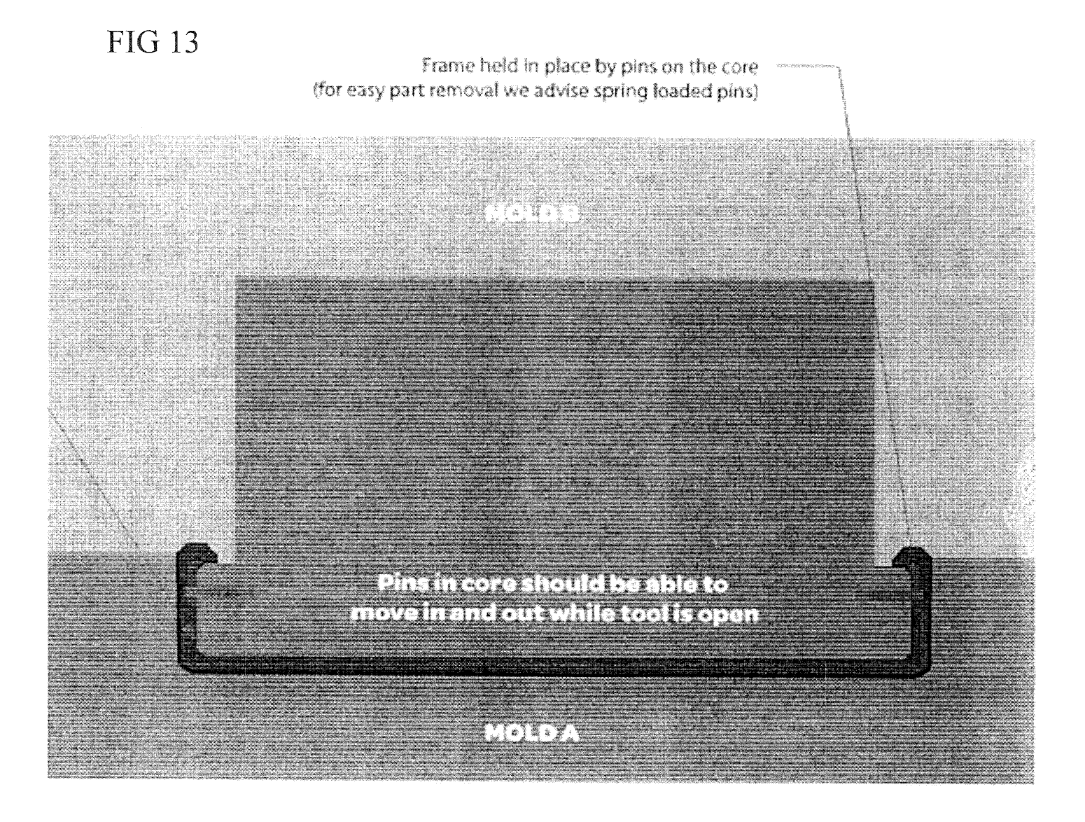

FIG. 13 depicts an embodiment of the molding process where the frame insert is retained on retractable or spring-loaded pins during the over molding step. The use of such pins make removal of the part easier and repetitive.

While the invention has been described and illustrated in connection with embodiments, many variations and modifications as will be evident to those skilled in this art may be made without departing from the spirit and scope of the invention as defined by the claims, and the invention is thus not to be limited to the precise details of methodology or construction set forth above as such variations and modifications are intended to be included within the scope of the invention as defined by the claims.

1. A case for enclosing a personal electronic device comprising:
a first layer co-molded with a second layer and permanently affixed together to form a one-piece assembly; and
a reinforcing member,
wherein the first layer includes a bottom surface, side surfaces joined to the bottom surface and extending upward therefrom, and a fitted cavity configured to accept and retain the personal electronic device such that the bottom surface covers at least a portion of a bottom surface of the inserted personal electronic device and the side surfaces cover at least a portion of a side surface of the inserted personal electronic device;
wherein the second layer includes a bottom surface and side surfaces sized and shaped to cover an exterior of the bottom and side surfaces of the first layer, and
wherein the reinforcing member is configured to strengthen areas of the second layer.

2. The case of claim 1 wherein the reinforcing member is an adhesive film.

3. The case of claim 1 wherein the reinforcing member is a frame.

4. The case of claim 3 wherein the material for the frame is selected from one of the following:
plastic, poly carbonate, and metal.
